(19) United States
(12) Patent Application Publication
(10) Pub. No.: US 2018/0083163 A1
(43) Pub. Date: Mar. 22, 2018

(54) LIGHT-EMITTING DEVICE AND METHOD OF MANUFACTURING THE SAME

(71) Applicant: TQYQDA GOSEI CO. , LTD., Kiyosu-shi (JP)

(72) Inventors: Yoshiki SAITO, Kiyosu-shi (JP); Daisuke SHINODA, Kiyosu-shi (JP); Akira TANEICHI, Kiyosu-shi (JP); Hisayuki MIKI, lchihara (JP); Kazutaka YOSHIMURA, lchihara (JP)

(73) Assignee: TQYQDA GOSEI CO. , LTD.

(21) Appl. No.: 15/658,195

(22) Filed: Jul. 24, 2017

(30) Foreign Application Priority Data
Sep. 21, 2016 (JP) 2016-184860
Jul. 18, 2017 (JP) 2017-139245

(51) Int. Cl. H01L 33/32; H01L 33/22; H01L 33/00; H01L 33/42

(52) U.S. Cl. CPC H01L 33/32; H01L 33/22; H01L 33/42; H01L 33/0075; H01L 33/0095

(57) ABSTRACT

A method of manufacturing a light-emitting device includes forming by sputtering a nucleation layer mainly including AlN on a surface of a patterned substrate including a concave-convex pattern, after forming the nucleation layer, performing a heat treatment at a temperature of not less than 1150° C., after the heat treatment, forming an AlGaN underlayer on the surface of the patterned substrate with the nucleation layer formed thereon, the AlGaN underlayer mainly including AlₓGa₁₋ₓN (0.04≦x≦1) and a flat surface, and epitaxially growing a group III nitride semiconductor on the AlGaN underlayer so as to form a light-emitting function portion including a light-emitting layer.

The present application is based on Japanese patent application Nos. 2016-184860 and 2017-139245 filed on Sep. 21, 2016 and Jul. 18, 2017, respectively, the entire contents of which are incorporated herein by reference.

### BACKGROUND OF THE INVENTION

### 1. Field of the Invention

The invention relates to a light-emitting device and a method of manufacturing the light-emitting device.

### 2. Description of the Related Art

An ultraviolet-light-emitting device is known in which a light-emitting layer made of a gallium nitride-based compound semiconductor is formed on a sapphire substrate having a predetermined concave-convex pattern on its surface via a low-dislocation-density AlN layer (see e.g. JP-A-2005-12063).

As for the ultraviolet-light-emitting device disclosed by JP-A-2005-12063, the low-dislocation-density layer to reduce threading dislocations with certain thickness is grown on the substrate having a predetermined concave-convex pattern on its surface by MOCVD. In addition, AlN is used to form the low-dislocation-density layer so that ultraviolet light emitted from the light-emitting layer is prevented from being absorbed.

Also, a light-emitting device is known in which a group III nitride semiconductor layer is formed on a sapphire substrate having plural hemispherical bumps on the upper surface via a buffer layer made of AlₓGa₁₋ₓN (0≦x≦1) (see e.g. JP-A-2010-103578).

As for the light-emitting device disclosed by JP-A-2010-103578, optical confinement in the light-emitting device can be reduced by using the substrate having plural hemispherical bumps on the upper surface, and light extraction efficiency thereby can be improved. Here, to uniformly form the buffer layer on the upper surface of the substrate having plural hemispherical bumps, sputtering with highly linear material particle ejection is used to form the buffer layer.

Also, a light-emitting device is known in which a group III nitride layer is formed on a sapphire substrate via a growth underlayer made of AlₚGa₁₋ₚN (0.8≦p≦1) (see e.g. JP-B-5898347).

As for the process of manufacturing the light-emitting device disclosed by JP-B-5898347, heat treatment is performed at not less than 1250° C. after forming the growth underlayer to improve crystal quality of the group III nitride layer. This heat treatment is particularly effective to reduce dislocations in the growth underlayer formed using the MOCVD method and to eliminate pits or prevent hillocks on the surface.

### SUMMARY OF THE INVENTION

Through the intense study, the inventors found that when an AlGaN layer formed of an AlGaN-based material is formed on a substrate having a concave-convex pattern on a surface via an AlN layer, the dislocation density and surface condition of the AlGaN layer greatly vary depending on the condition of the AlN layer.

In general, AlGaN-based materials with a higher Al content have a higher melting point and it is difficult to form a high-quality and low-screw-dislocation AlN layer on a substrate having a concave-convex pattern on a surface. This is considered to be one of reasons why it is difficult to form an AlGaN layer having a low dislocation density.

In addition, it was also found that when growing AlGaN on the AlN layer, it is highly probable that grooves caused by the concave-convex pattern on the substrate surface remain on the upper surface of the AlGaN layer under the usual growth conditions, unlike when growing a film not containing a large amount of Al, such as GaN film.

None of JP-A-2005-12063, JP-A-2010-103578 and JP-B-5898347 teaches the above problems and thus obviously discloses any means for solving the problems.

It is an object of the invention to provide a light-emitting device that allows the AlGaN layer to have a low dislocation density and a flat surface, where the AlGaN layer is formed via the AlN layer on the surface of the substrate with the concave-convex pattern, as well as a method of manufacturing the light-emitting device.

According to embodiments of the invention, a method of manufacturing a light-emitting device defined by [1] to [3] below and a light-emitting device defined by [4] to [7] below are provided.

[1] A method of manufacturing a light-emitting device, comprising:

forming by sputtering a nucleation layer mainly comprising AlN on a surface of a patterned substrate comprising a concave-convex pattern;

after forming the nucleation layer, performing a heat treatment at a temperature of not less than 1150° C.;

after the heat treatment, forming an AlGaN underlayer on the surface of the patterned substrate with the nucleation layer formed thereon, the AlGaN underlayer mainly comprising AlₓGa₁₋ₓN (0.04≦x≦1) and a flat surface; and

epitaxially growing a group III nitride semiconductor on the AlGaN underlayer so as to form a light-emitting function portion comprising a light-emitting layer.

[2] The method according to [1], wherein the AlGaN underlayer mainly comprises AlₓGa₁₋ₓN (0.04≦x≦0.15).

[3] The method according to [1], wherein the AlGaN underlayer mainly comprises AlₓGa₁₋ₓN (0.6≦x≦1.0).

[4] A light-emitting device, comprising:

a patterned substrate with a concave-convex pattern that comprises a flat portion and a plurality of convex portions;

a nucleation layer that mainly comprises AlN, includes O₂ at a concentration of not less than 1×10¹⁷ cm⁻³ and is formed on the patterned substrate;

an AlGaN underlayer that mainly comprises AlₓGa₁₋ₓN (0.04≦x≦1), is formed on the patterned substrate via the nucleation layer and has a flat surface; and

a light-emitting function portion that comprises a group III nitride semiconductor, is formed on the AlGaN underlayer and comprises a light-emitting layer,

wherein the nucleation layer is configured such that a growth amount of the AlGaN underlayer from the flat portion is larger than that from the convex portions of the patterned substrate so as to allow the AlGaN underlayer to have a flat surface.

[5] The light-emitting device according to [4], wherein the AlGaN underlayer mainly comprises (0.04≦x≦0.15).

[6] The light-emitting device according to [4], wherein the AlGaN underlayer mainly comprises AlₓGa₁₋ₓN (0.6≦x≦1.0).

[7] The light-emitting device according to any one of [4] to [6], wherein the nucleation layer has a dislocation density of not more than 7×10⁸/cm².

### Effects of the Invention

According to an embodiment of the invention, a light-emitting device can be provided that allows the AlGaN layer to have a low dislocation density and a flat surface, where the AlGaN layer is formed via the AlN layer on the surface of the substrate with the concave-convex pattern, as well as a method of manufacturing the light-emitting device.

### BRIEF DESCRIPTION OF THE DRAWINGS

Next, the present invention will be explained in more detail in conjunction with appended drawings, wherein:

FIG. 1A is a vertical cross-sectional view showing a light-emitting device in an embodiment;

FIG. 1B is an enlarged view showing an underlayer and the periphery thereof in the light-emitting device of FIG. 1A;

FIGS. 2A to 2E are vertical cross-sectional views showing a process of manufacturing the light-emitting device in the embodiment;

FIG. 3A is a bird's eye view SEM image showing the state during growth of a GaN underlayer which is grown instead of an underlayer including mainly AlGaN in the embodiment;

FIG. 3B is a bird's eye view SEM image showing the state during growth of an AlₓGa₁₋ₓN underlayer (x=0.1) when heat treatment of not less than 1150° C. is not performed after forming a nucleation layer;

FIG. 4A is an AFM (atomic force microscope) image showing the state during growth of an AlₓGa₁₋ₓN underlayer (x=0.04) when heat treatment of not less than 1150° C. is not performed after forming the nucleation layer;

FIG. 4B is an AFM image showing the state during growth of an AlₓGa₁₋ₓN underlayer (x=0.1) when heat treatment of not less than 1150° C. is not performed after forming the nucleation layer; and

FIG. 4C is an AFM image showing the state during growth of an AlₓGa₁₋ₓN underlayer (x=0.1) when heat treatment of not less than 1150° C. is performed after forming the nucleation layer.

### DETAILED DESCRIPTION OF THE PREFERRED EMBODIMENTS

### Embodiment

Configuration of Light-Emitting Device

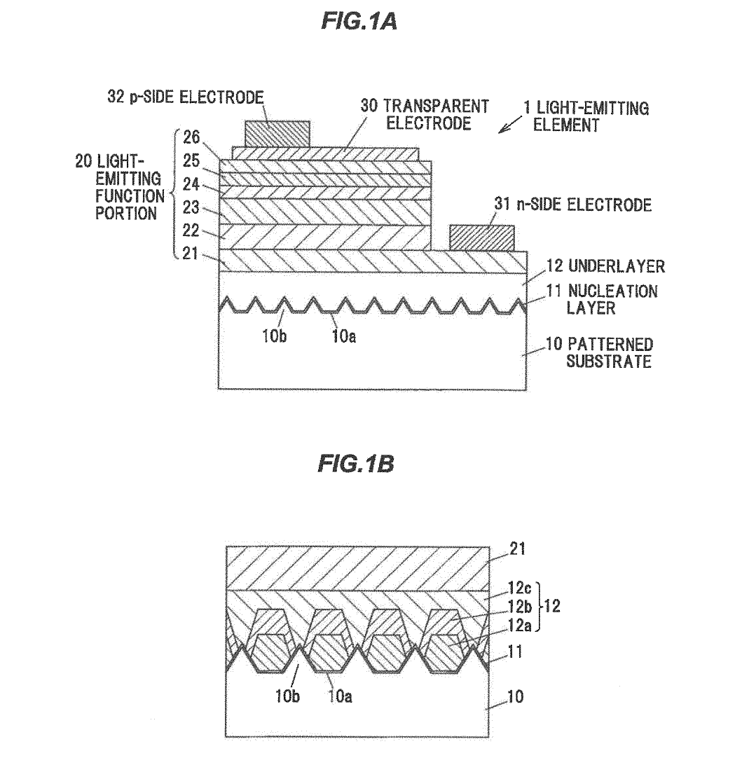

FIG. 1A is a vertical cross-sectional view showing a light-emitting device 1 in an embodiment. The light-emitting device 1 has a patterned substrate 10, a nucleation layer 11 which includes mainly AlN and is formed on the patterned substrate 10, an underlayer 12 which includes mainly AlₓGa₁₋ₓN (0.04≦x≦1) and is formed on the patterned substrate 10 via the nucleation layer 11, and a light-emitting function portion 20 which is formed of a group III nitride semiconductor, is formed on the underlayer 12 and includes a light-emitting layer.

FIG. 1B is an enlarged view showing the underlayer 12 and the periphery thereof in the light-emitting device 1 of FIG. 1A. The underlayer 12 is composed of a first layer 12a, a second layer 12b on the first layer 12a, and a third layer 12c on the second layer 12b.

Patterned Substrate

A concave-convex pattern composed of a flat portion 10a and plural convex portions 10b is provided on a surface of the patterned substrate 10. Optical confinement in the light-emitting device 1 is reduced by diffuse reflection of light at the concave-convex pattern, and light extraction efficiency is thereby improved.

The patterned substrate 10 is a substrate on which a group III nitride compound semiconductor crystal is epitaxially grown, and it is possible to use, e.g., a sapphire substrate, a SiC substrate or a Si substrate, etc., for the patterned substrate 10. It is particularly preferable to use a sapphire substrate to reduce ultraviolet light absorption.

The principal surface of the patterned substrate 10 is, e.g., a c-plane. In this case, a surface of the flat portion 10a is the c-plane and the inclined surfaces of the convex portions 10b are different planes from the c-plane.

The shape of the convex portion 10b is, e.g., a circular cone or a polygonal pyramid, but is not specifically limited as long as it is a shape formed by different planes from the c-plane. In addition, the convex portions 10b are arranged in a triangular lattice pattern or a square lattice pattern in a plan view.

The concave-convex pattern on the patterned substrate 10 is formed by, e.g., photolithography and etching.

Nucleation Layer

The nucleation layer 11, which is a layer formed on the surface of the patterned substrate 10 and including mainly AlN, reduces a difference in lattice constant between the patterned substrate 10 and the underlayer 12 and facilitates epitaxial growth of the underlayer 12.

The nucleation layer 11 is formed by depositing AlN on the surface of the patterned substrate 10 using sputtering and then performing heat treatment (annealing) at a temperature of not less than 1150° C. The heat treatment temperature here is preferably not more than the decomposition temperature of the patterned substrate 10, e.g., not more than 1450° C. in case of the sapphire substrate.

Crystal defects can be reduced when the nucleation layer 11 is formed by sputtering. It is particularly effective to reduce screw dislocations, or mixed dislocations including screw dislocations. When, e.g., an AlN nucleation layer is formed on the patterned substrate 10 which is a sapphire substrate, the dislocation density is about 1×10⁹/cm² in a nucleation layer formed by MOCVD and is not more than 7×10⁸/cm² in a nucleation layer formed by sputtering. In other words, use of sputtering to form the nucleation layer can reduce the dislocation density by not less than 30% as compared to when using MOCVD.

In light-emitting devices formed using a group III nitride semiconductor, InGaN is generally used as a material of the light-emitting layer. Ultraviolet-light-emitting devices have a smaller In composition (or they may include no indium) in InGaN of the light-emitting layer than visible light-emitting devices and thus have a low power. Therefore, for ultraviolet-light-emitting devices, it is especially important to prevent a decrease in output power due to dislocation in the vicinity of the light-emitting layer.

The dislocation density of the nucleation layer 11 can be reduced by using sputtering and the dislocation density of a layer epitaxially grown on the nucleation layer 11 can be thereby reduced. Therefore, it is possible to prevent a decrease in output power of the light-emitting device 1 due to dislocation in the vicinity of the light-emitting layer. In addition, since the dislocation density of the layer epitaxially grown on the nucleation layer 11 can be reduced, a leakage current can be also reduced. For example, by reducing the dislocation density of the nucleation layer 11 to not more than 7×10⁸/cm², the dislocation density of the underlayer 12, which is formed on the nucleation layer 11, can be also reduced to not more than 7×10⁸/cm².

The nucleation layer 11 formed by sputtering is closer to a single crystal than the nucleation layer formed by MOCVD, and is typically a multi-domain single crystal. The nucleation layer formed by MOCVD is generally polycrystalline or amorphous.

The nucleation layer 11 formed by sputtering in the present embodiment is characterized by containing oxygen (O₂) (e.g., not less than 1×10¹⁷/cm³). The nucleation layer formed by MOCVD contains nearly no oxygen.

In addition, the nucleation layer 11 formed by sputtering in the present embodiment has a lower C concentration (e.g., not more than 1×10¹⁷/cm³) than the nucleation layer formed by MOCVD.

In addition, the nucleation layer 11 formed by sputtering in the present embodiment is characterized by containing Ar (e.g., not less than 1×10¹⁶/cm³) which is an inert gas atom used for sputtering.

When GaN or AlGaN is grown on a patterned substrate via an AlN layer, GaN or AlGaN with low Al composition generally mainly grows from a flat portion of the concave-convex pattern of the patterned substrate and very little from the convex portions. On the other hand, when AlGaN with high Al composition is grown to form an ultraviolet-light-emitting device, AlGaN grows not only from the flat portion but also from the convex portions of the concave-convex pattern of the patterned substrate and grooves caused by the concave-convex pattern of the patterned substrate may remain on the surface of the AlGaN layer.

As a result of intense study, the inventors found that when an AlN layer formed on a patterned substrate by sputtering is heat-treated at a temperature of not less than 1150° C., the growth amount of AlGaN with high Al composition from the convex portions of the concave-convex pattern of the patterned substrate can be less than when heat treatment is not performed. As a result, grooves caused by the concave-convex pattern of the patterned substrate do not remain on a surface and an AlGaN layer having a flat surface can be obtained.

That is, in the present embodiment, it is necessary to perform heat treatment after sputtering in the step of forming the nucleation layer 11 to allow AlGaN constituting the underlayer 12 to grow easily from the flat portion 10a and hard from the convex portions 10b on the surface of the patterned substrate 10, so that grooves caused by the concave-convex pattern of the patterned substrate do not remain on a surface of the underlayer 12.

Therefore, the nucleation layer 11 serves to make the underlayer 12 grow more from the flat portion 10a and less from the convex portions 10b of the patterned substrate 10 so that the grooves on the surface of the underlayer 12 are filled during the growth of the underlayer 12.

It is presumed that the portion of the nucleation layer 11 formed on the convex portions 10b may be partially or entirely removed or move onto the flat portion 10a due to the heat treatment and this is the reason why AlGaN constituting the underlayer 12 is likely to grow from the flat portion 10a and less likely to grow from the convex portions 10b on the surface of the patterned substrate 10.

Underlayer

The underlayer 12 is a layer including mainly AlGaN to be a base to grow the light-emitting function portion 20, and has a flat surface without the grooves caused by the concave-convex pattern of the patterned substrate 10. The underlayer 12 is composed of the first layer 12a, the second layer 12b and the third layer 12c, as previously described.

The first layer 12a is a layer formed by facet growth with few lateral crystal growth components, and can distort the direction of motion of the dislocation to form a half-loop, thereby reducing the dislocations. The third layer 12c is a layer formed with many lateral crystal growth components, and can fill the grooves on the AlGaN surface caused by the concave-convex pattern on the surface of the patterned substrate 10. The second layer 12b is formed under intermediate conditions between the growth conditions for the first layer 12a and the growth conditions for the third layer 12c.

The underlayer 12 with a low dislocation density and a flat surface can be obtained by forming by the first layer 12a, the second layer 12b and the third layer 12c as described above. The underlayer 12 is formed by, e.g., the MOCVD method.

The method used to increase the lateral crystal growth components is, e.g., to reduce growth pressure, to raise the growth temperature, or to increase the flow rate of NH₃ gas which is a source gas of AlGaN. To reduce the lateral crystal growth components, a reverse is performed.

Meanwhile, the Al composition in AlGaN constituting the underlayer 12 is set to a value at which the underlayer 12 does not absorb light emitted from the light-emitting layer of the light-emitting function portion 20.

Since higher Al composition leads to wider bandgap of AlGaN, absorption of shorter-wavelength light by the underlayer 12 can be prevented. However, since AlGaN with higher Al composition is more likely to grow from the convex portions 10b on the surface of the patterned substrate 10 as described above, the grooves caused by the concave-convex pattern of the patterned substrate 10 are likely to remain on the surface of the underlayer 12.

Therefore, the value of the Al composition in AlGaN constituting the underlayer 12, which is set so that the underlayer 12 does not absorb light emitted from the light-emitting layer of the light-emitting function portion 20, is preferably as small as possible.

When the emission wavelength of the light-emitting device 1 is within a wavelength range called UV-A (400 to 315 nm), the Al composition x in AlₓGa₁₋ₓN constituting the underlayer 12 is preferably set to not less than 0.04. For example, the Al composition x in AlₓGa₁₋ₓN constituting the first layer 12a is 0.04 to 0.15, the Al composition x in AlₓGa₁₋ₓN constituting the second layer 12b is 0.09 and the Al composition x in AlₓGa₁₋ₓN constituting the third layer 12c is 0.10.

Meanwhile, when the underlayer 12 includes contains a donor such as Si, the Al composition x needs to increase by about 0.01. This makes more difficult to flatten the surface of the underlayer 12 since AlGaN with higher Al composition is more likely to grow from the convex portions 10b on the surface of the patterned substrate 10. Therefore, the first layer 12a, the second layer 12b and the third layer 12c are preferably formed of undoped AlGaN.

When the emission wavelength of the light-emitting device 1 is within a wavelength range called UV-B (315 to 280 nm), the Al composition x in AlₓGa₁₋ₓN (undoped) constituting the underlayer 12 is preferably set to 0.35 to 0.65. For example, the Al composition x in AlₓGa₁₋ₓN constituting the first layer 12a is 0.4 to 0.65, the Al composition x in AlₓGa₁₋ₓN constituting the second layer 12b is 0.35 to 0.6 and the Al composition x in AlₓGa₁₋ₓN constituting the third layer 12c is 0.4 to 0.65.

When the emission wavelength of the light-emitting device 1 is within a wavelength range called UV-C (less than 280 nm), the Al composition x in AlₓGa₁₋ₓN (undoped) constituting the underlayer 12 is preferably set to not less than 0.6. For example, the Al composition x in AlₓGa₁₋ₓN constituting the first layer 12a is 1, the Al composition x in AlₓGa₁₋ₓN constituting the second layer 12b is 0.6 to 1.0 and the Al composition x in AlₓGa₁₋ₓN constituting the third layer 12c is 0.6 to 1.0.

Light-Emitting Function Portion

The light-emitting function portion 20 has an n-contact layer 21, an n-cladding layer 22 on the n-contact layer 21, a light-emitting layer 23 on the n-cladding layer 22, an electron blocking layer 24 on the light-emitting layer 23, a p-cladding layer 25 on the electron blocking layer 24, and a p-contact layer 26 on the p-cladding layer 25.

The n-contact layer 21 is connected to an n-side electrode 31, and the p-contact layer 26 is connected to a p-side electrode 32 via a transparent electrode 30 which is formed on the p-contact layer 26.

The light-emitting function portion 20 includes mainly a group III nitride semiconductor and is formed by, e.g., the MOCVD method. Since the grooves caused by the concave-convex pattern of the patterned substrate 10 do not exist on the surface of the underlayer 12, the light-emitting function portion 20 grown on the underlayer 12 has excellent crystal quality. A donor and an acceptor used for the light-emitting function portion 20 are, e.g., respectively Si and Mg.

The n-contact layer 21 and the n-cladding layer 22 are formed of, e.g., AlGaN containing Si as a donor. The light-emitting layer 23 has, e.g., a MQW (Multiple Quantum Well) structure formed of an AlGaN-based material. The electron blocking layer 24 is formed of AlGaN containing Mg as an acceptor. The p-cladding layer 25 is formed of GaN containing Mg. The p-contact layer 26 is formed of AlGaN containing Mg as an acceptor. The compositional ratio of AlGaN constituting each layer is appropriately determined according to the emission wavelength of the light-emitting layer 23.

The n-side electrode 31 and the p-side electrode 32 are formed of a conductive material such as Au. Meanwhile, the transparent electrode 30 is formed of a transparent material such as ITO (In₂O₃—SnO₂).

Process of Manufacturing the Light-Emitting Device

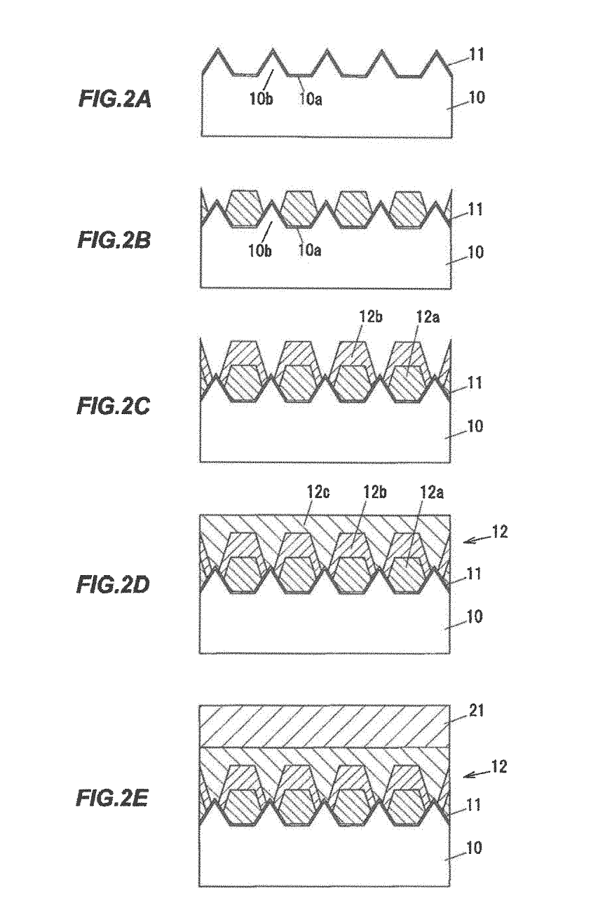

FIGS. 2A to 2E are vertical cross-sectional views showing a process of manufacturing the light-emitting device 1 in the embodiment.

Firstly, as shown in FIG. 2A, the nucleation layer 11 includes mainly AlN is formed on the patterned substrate 10 by the sputtering method.

When the nucleation layer 11 having a single crystal structure is formed, the flow rate ratio of nitrogen source to inert gas is desirably adjusted so that 50% to 100%, desirably 75%, of the chamber is the nitrogen source. Meanwhile, when the nucleation layer 11 having a columnar crystal (polycrystalline) is formed, the flow rate ratio of nitrogen source to inert gas is desirably adjusted so that the 1% to 50%, desirably 25%, of the chamber is nitrogen source.

The patterned substrate 10 is preferably pre-treated before forming the nucleation layer 11 on the patterned substrate 10. For example, as the pretreatment, the patterned substrate 10 can be cleaned by exposure to Ar or N₂ plasma to remove organic substances or oxides attached onto the surface of the patterned substrate 10. In this case, when voltage is applied between the patterned substrate 10 and the chamber without applying power to the sputter target, plasma particles efficiently act on the patterned substrate 10.

In addition, the pretreatment of the patterned substrate 10 is preferably plasma treatment performed in an atmosphere in which an ion component such as N⁺ or (N₂)⁺ is mixed with a radical component not having an electric charge such as N radical or N₂ radical. When the plasma treatment performed in an atmosphere with a mixture of ion and radical components as described above is used for pretreatment of the patterned substrate 10 so that reactive species with an appropriate energy acts on the patterned substrate 10, contaminants, etc., can be removed without damaging the surface of the patterned substrate 10.

Next, as shown in FIGS. 2B to 2D, the underlayer 12 is obtained by sequentially forming the first layer 12a, the second layer 12b and the third layer 12c on the patterned substrate 10 via the nucleation layer 11.

When the underlayer 12 is deposited by the MOCVD method, for example, hydrogen (H₂) or nitrogen (N₃) are used as a carrier gas, trimethylgallium (TMG) or triethylgallium (TEG) is used as a Ga source, trimethylaluminum (TMA) or trimethylaluminum (TEA) is used as an Al source, and ammonium (NH₃) or hydrazine (N₂H₄) is used as an N source. In addition, when a dopant is added, it is possible to use monosilane (SiH₄) or disilane (Si₂H₆) as a Si source and cyclopentadienyl magnesium (Cp₂Mg) as an Mg source.

The first layer 12a is formed by facet growth with few lateral crystal growth components, and the second layer 12b and the third layer 12c are formed with more lateral crystal growth components than first layer 12a. In detail, the growth pressure is adjusted to, e.g., not less than 40 kPa, preferably about 60 kPa for the first layer 12a and not more than 40 kPa, preferably about 20 kPa for the second layer 12b and the third layer 12c.

When the growth pressure for the first layer 12a is not less than 40 kPa, the growth temperature is preferably not more than 1140° C., more preferably about 1120° C., to prevent pits on the surface of the underlayer 12.

Next, as shown in FIG. 2E, the n-contact layer 21 is formed on the underlayer 12. Then, various members on the n-contact layer 21 are formed by a known process and the light-emitting device 1 is thereby obtained.

Effects of the Embodiment

In the embodiment, although the substrate is a patterned substrate having a concave-convex pattern on a surface and an underlayer as a base to grow the light-emitting function portion thereon is a layer including mainly AlGaN with high Al composition, it is possible to reduce the dislocation density of the underlayer and also to flatten the surface of the underlayer without grooves caused by the concave-convex pattern of the patterned substrate. As a result, it is possible to improve crystal quality of the light-emitting function portion formed on the underlayer, to improve internal quantum efficiency, etc., of the light-emitting device, and also to reduce a leakage current.

### EXAMPLES

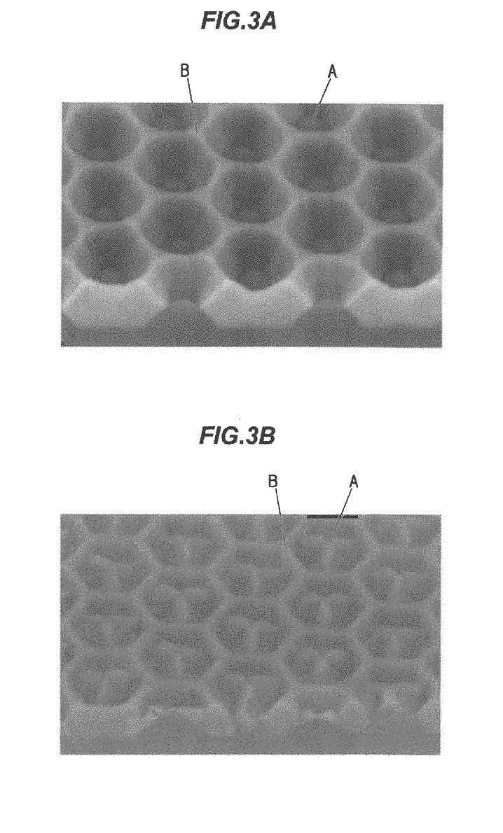

FIG. 3A is a bird's eye view SEM image showing the state during growth of a GaN underlayer which is grown instead of the underlayer 12 including mainly AlGaN in the embodiment. Heat treatment of not less than 1150° C. after formation of the nucleation layer 11 was not performed before forming the GaN underlayer.

As described for the embodiment, GaN or AlGaN with low Al composition mainly grows from the flat portion 10a of the concave-convex pattern of the patterned substrate 10 and very little from the convex portions 10b. Therefore, facets were clearly formed on the GaN underlayer during the growth, as shown in FIG. 3A.

A portion indicated by “A” in FIG. 3A is located immediately above the top of the convex portion 10b of the concave-convex pattern of the patterned substrate 10. Meanwhile, a portion indicated by “B” is an upper surface of the GaN underlayer which spread as the growth progressed, and the grooves on the surface of the GaN underlayer caused by the concave-convex pattern of the patterned substrate 10 would be filled as the growth continued and the surface of the GaN underlayer would become flat.

That is, when forming the GaN underlayer, heat treatment of not less than 1150° C. after formation of the nucleation layer 11 is not necessary. However, the GaN underlayer absorbs ultraviolet light and is thus unsuitable for ultraviolet-light-emitting device.

FIG. 3B is a bird's eye view SEM image showing the state during growth of the AlₓGa₁₋ₓN underlayer 12 (x=0.1) when heat treatment of not less than 1150° C. is not performed after forming the nucleation layer 11.

This underlayer 12 contained Al and thus grew also from the convex portions 10b of the concave-convex pattern of the patterned substrate 10. In addition, since heat treatment was not performed after forming the nucleation layer 11, growth from the convex portions 10b was not suppressed and an abnormally-grown crystal appeared at a portion located immediately above the top of the convex portion 10b indicated by “A”, as shown in FIG. 3B. Therefore, the grooves on the surface of the underlayer 12 caused by the concave-convex pattern of the patterned substrate 10 would not be filled even though the growth continued.

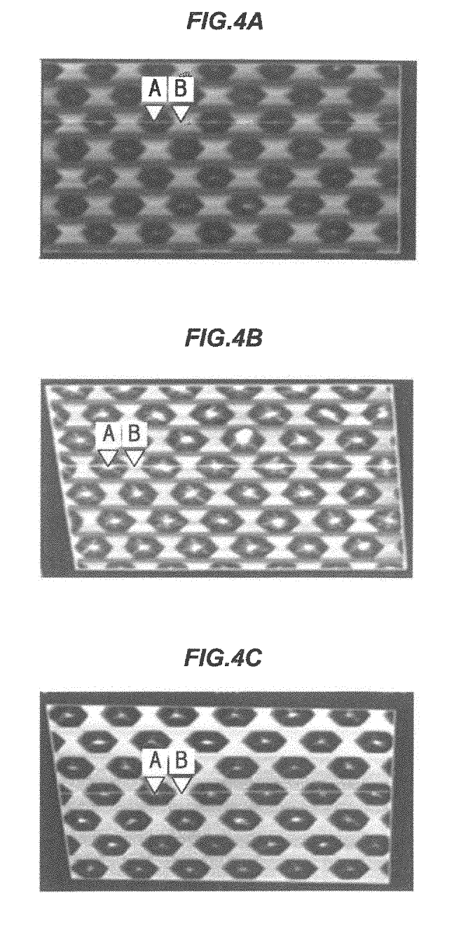

FIG. 4A is an AFM (atomic force microscope) image showing the state during growth of the AlₓGa₁₋ₓN underlayer (x=0.04) when heat treatment of not less than 1150° C. is not performed after forming the nucleation layer 11.

FIG. 4B is an AFM image showing the state during growth of the AlₓGa₁₋ₓN underlayer 12 (x=0.1) when heat treatment of not less than 1150° C. is not performed after forming the nucleation layer 11.

FIG. 4C is an AFM image showing the state during growth of the AlₓGa₁₋ₓN underlayer 12 (x=0.1) when heat treatment of not less than 1150° C. is performed after forming the nucleation layer 11.

The portions indicated by “A” and “B” in FIGS. 4A to 4C correspond to the portions indicated by “A” and “B” in FIGS. 3A and 3B.

In FIG. 4A, an abnormally-grown crystal observed at the portion indicated by “A” is small. It is considered that this is because the Al composition in the underlayer was low. However, (x=0.04) absorbs ultraviolet light and is thus unsuitable for ultraviolet-light-emitting device.

In FIG. 4B, a large abnormally-grown crystal is observed at the portion indicated by “A”. It is considered that this is because the Al composition in the underlayer was high and heat treatment was not performed after forming the nucleation layer 11.

On the other hand, an abnormally-grown crystal observed at the portion indicated by “A” in FIG. 4C is smaller than that observed in FIG. 4B. It is considered that this is because growth of the underlayer 12 from the convex portions 10b was suppressed by heat treatment after formation of the nucleation layer 11.

Although the embodiment and examples of the invention have been described, the invention is not intended to be limited to the embodiment and examples, and the various kinds of modifications can be implemented without departing from the gist of the invention. For example, the configuration of the light-emitting device is not specifically limited as long as the patterned substrate 10, the nucleation layer 11, an underlayer and an ultraviolet-light emitting layer are included.

In addition, the invention according to claims is not to be limited to the embodiment and examples. Further, please note that all combinations of the features described in the embodiment and examples are not necessary to solve the problem of the invention.

What is claimed is:

1. A method of manufacturing a light-emitting device, comprising:
forming by sputtering a nucleation layer mainly comprising AlN on a surface of a patterned substrate comprising a concave-convex pattern;
after forming the nucleation layer, performing a heat treatment at a temperature of not less than 1150° C.;
after the heat treatment, forming an AlGaN underlayer on the surface of the patterned substrate with the nucleation layer formed thereon, the AlGaN underlayer mainly comprising AlₓGa₁₋ₓN (0.04≦x≦1) and a flat surface; and
epitaxially growing a group III nitride semiconductor on the AlGaN underlayer so as to form a light-emitting function portion comprising a light-emitting layer.

2. The method according to claim 1, wherein the AlGaN underlayer mainly comprises AlₓGa₁₋ₓN (0.04≦x≦0.15).

3. The method according to claim 1, wherein the AlGaN underlayer mainly comprises AlₓGa₁₋ₓN (0.6≦x≦1).

4. A light-emitting device, comprising:
a patterned substrate with a concave-convex pattern that comprises a flat portion and a plurality of convex portions;
a nucleation layer that mainly comprises AlN, includes O₂ at a concentration of not less than 1×10¹⁷ cm⁻³ and is formed on the patterned substrate;
an AlGaN underlayer that mainly comprises AlₓGa₁₋ₓN (0.04≦x≦1), is formed on the patterned substrate via the nucleation layer and has a flat surface; and
a light-emitting function portion that comprises a group III nitride semiconductor, is formed on the AlGaN underlayer and comprises a light-emitting layer,
wherein the nucleation layer is configured such that a growth amount of the AlGaN underlayer from the flat portion is larger than that from the convex portions of the patterned substrate so as to allow the AlGaN underlayer to have a flat surface.

5. The light-emitting device according to claim 4, wherein the AlGaN underlayer mainly comprises AlₓGa₁₋ₓN (0.04≦x≦0.15).

6. The light-emitting device according to claim 4, wherein the AlGaN underlayer mainly comprises AlₓGa₁₋ₓN (0.6≦x≦1.0).

7. The light-emitting device according to claim 4, wherein the nucleation layer has a dislocation density of not more than 7×10⁸/cm².
